(19) United States
(12) Patent Application Publication
(10) Pub. No.: US 2021/0344757 A1
(43) Pub. Date: Nov. 4, 2021

(54) COMMUNICATION MODULE

(71) Applicant: Siemens Aktiengesellschaft, Muenchen (DE)

(72) Inventors: Johann SEITZ, Amberg (DE); Sandro PACHMANN, Illschwang (DE)

(73) Assignee: Siemens Aktiengesellschaft, Muenchen (DE)

(21) Appl. No.: 17/236,034

(22) Filed: Apr. 21, 2021

(30) Foreign Application Priority Data
Apr. 30, 2020 (EP) 20172379.8

(51) Int. Cl. H04L 29/08; G08C 19/00; H01H 47/02

(52) U.S. Cl. CPC H04L 67/12; H01H 89/00; H01H 47/02; G08C 19/00

(57) ABSTRACT

A communication module is for attachment to a parameterizable switching device. In an embodiment, the switching device includes one or more setting elements for setting parameter values. The communication module, attached at a defined position relative to the switching device, covers one or more of the one or more setting elements.

### PRIORITY STATEMENT

The present application hereby claims priority under 35 U.S.C. § 119 to European patent application number EP20172379.8 filed Apr. 30, 2020, the entire contents of each of which are hereby incorporated herein by reference.

### FIELD

Embodiments of the invention relates to a communication module, a parameterizable switching device, and a method for converting the parameterization of a switching device to remote parameterization. The invention similarly relates to a computer program product with which the method can be carried out.

### BACKGROUND

Different parameterizable switching devices such as electronic motor starters, function relays, etc., have setting elements, e.g. with a potentiometer, a rotary coding switch or a rotary selection switch with which parameters from a user can be predefined directly on the device. The SIRIUS 3RW50 soft starter manufactured by Siemens AG, for example, has setting elements for the manual setting of the parameters for start-up voltage, start-up ramp time, current limitation value, rated operating current of the motor, CLASS setting for motor overload trip classes (e.g. 10A, 10E, 20E) and deceleration time via a screwdriver. With switching devices of this type, the set parameter value can be read from a scale indicator of the setting elements.

If a switching device of this type is integrated into a communication network via an additional communication module or is equipped with an additional input unit, e.g. an HMI, the switching device can also be parameterized remotely via the communication network, which is also referred to below as remote parameterization (HMI=Human Machine Interface). For example, 3RW5 communication modules are available for integrating the Siemens SIRIUS 3RW5 soft starter into fieldbus systems such as Profinet, Profibus, Ethernet/IP, Modbus RTU or Modbus TCP.

A conflict can therefore arise between parameters which are settable directly on the device and parameters which are settable through remote parameterization: the problem can occur that the parameter values displayed on the scale indicators of the setting elements differ from those predefined via the remote parameterization which are actually used within the device. This results in an ambiguous state for the user, or the user assumes incorrect setting values.

This problem has hitherto been solved e.g. by foregoing the alternative remote parameterization facility for defining the parameters settable via the setting elements in the switching devices. However, this can result in a restricted parameterization. The exclusion of the remote parameterization can restrict the precision of the parameterization, since the parameters settable directly on the device via setting elements can have a higher imprecision than the remotely settable parameters. With setting elements, the reproducibility of setting values with a defined accuracy is possible only if the setting elements are synchronized with one another at considerable expense.

### SUMMARY

The inventors have discovered that a different possibility for solving the problem resides in being able to select the type of parameterization via a setting option, but this can result in the user erroneously assuming that the values of the parameters set on the setting elements are valid, even though values set through remote parameterization are used in the device.

At least one embodiment of the invention is therefore directed to improving the parameterization of a parameterizable switching device.

At least one embodiment of the invention is directed to a communication module. The communication module is a module required for a functional expansion of the switching device in relation to communication. The communication module is suitable for releasable attachment to a parameterizable switching device so that it assumes a defined position relative to the switching device. To do this, the communication module has one or more attachment elements for the attachment of the communication module at a precisely defined position on the switching device, the attachment elements thus acting as positioning device(s). The expression “at a precisely defined position” means that the communication module can be attached via the attachment elements at a defined position on the switching device. A parameterizable switching device is a switching device, e.g. a contactor, a relay or a motor starter, for which parameters can be predefined for its operation. For this purpose, the switching device has one or more setting elements arranged on an operating side of the switching device for setting a parameter value in each case for the individual parameters. A rotary control, for example, which bears a marking that can be set by a user to any value on a scale indicator can serve as a setting element. The setting element is connected via an operative connection to a potentiometer or a rotary coding switch which, as a component of an electrical circuit, defines a corresponding parameter value which is intended to be used during the operation of the switching device. The position defined for the communication model relative to the switching device is such that housing parts of the communication module cover one or more of the setting elements of the switching device when the communication module is attached to the switching device. The covered setting elements can therefore no longer be set and can no longer be read by a user.

At least one embodiment of the invention is further directed to a switching device. The switching device is parameterizable and for this purpose has one or more setting elements for setting parameter values of the switching device. The switching device is further designed in such a way that it interacts with a communication module, i.e. it provides a defined position for the attachment of the communication module. For this purpose, the switching device has one or more attachment elements for the attachment of a communication module at a precisely defined position on the switching device such that one or more of the setting elements of the switching device is covered by the communication module.

At least one embodiment of the invention is further directed to a method. This involves a method for converting the parameterization of a parameterizable switching device from a parameterization directly on the switching device to a remote parameterization, in particular via a communication network and/or a data line. The switching device has one or more setting elements by which parameter values can be set directly on the switching device. The method comprises a first method step in which a communication connection is set up between a communication module for remote parameterization and the switching device, wherein the communication module is attached to the switching device in such a way that the communication module covers one or more of the setting elements of the switching device. Through the setting up of the communication connection, the switching device is notified that the parameter values set on the setting elements are now no longer to be used for those parameters whose setting elements are covered by the communication module, but instead the parameter values which are received from the communication module. It is possible for the definition of the setting elements which are covered by the communication module to be transmitted from the communication module to the switching device. Two or more different communication modules which in each case cover different setting elements of the switching device and therefore also contain different definitions of the setting elements which are covered by the communication module can thus be assigned to one switching device. For permanent storage of the definition, a dataset associated with the communication module and containing this definition can be stored in a non-volatile electronic memory component of the communication module, e.g. an EEPROM (=Electrically Erasable Programmable Read Only Memory). The method also comprises a further step in which parameter values which are assigned to the covered setting elements are transmitted from the communication module via the communication connection to the switching device.

At least one embodiment of the invention is also achieved by a computer program product. This involves a computer program product for converting the parameterization of a parameterizable switching device. The computer program product is designed to be executable in a processor of the switching device. The computer program product can be designed to be storable as software, e.g. as a downloadable application software program (app for short), or as firmware in a memory of the communication module, and to be executable by the processor or a computing unit of the switching device. Alternatively or additionally, one or more functions of the computer program product can be designed as hardware, for example as an ASIC or in the form of a programmable logic circuit, e.g. an FPGA (ASIC =Application-Specific Integrated Circuit; FPGA=Field Programmable Gate Array).

The computer program product according to an embodiment of the invention is designed to carry out the method of an embodiment. The computer program product is therefore designed to carry out the method for converting the parameterization of a parameterizable switching device. In particular, it is designed to carry out the step of setting up a communication connection between a communication module for remote parameterization and the switching device. It is further designed to carry out the step of transmitting parameter values which are assigned to covered setting elements from the communication module via the communication connection to the switching device. The computer program product is designed according to the invention to implement and execute at least one embodiment of the described method for converting the parameterization. The computer program product can bring together all sub-functions of the method, i.e. it can be designed as monolithic.

Alternatively, the computer program product can also be designed as segmented and can in each case distribute sub-functions among segments which are executed on separate hardware. The computer program product can thus be designed to be executable partially in a processor of the switching device and partially in a processor of the communication module. One part of the method can further be carried out in the switching device and/or the communication module and another part of the method can be carried out in the control unit superordinate to the switching device and/or the communication model, such as, for example, a PLC, a manual parameterization device or a computer cloud (PLC=Programmable Logic Controller).

At least one embodiment of the invention is directed to a communication module for attachment to a parameterizable switching device, comprising:

one or more attachment elements for the attachment of the communication module to the switching device at a defined position; and housing parts to, upon the communication module being attached to the switching device, cover one or more setting elements, of the switching device, usable to set parameter values.

At least one embodiment of the invention is directed to a switching device, comprising:

one or more setting elements to set parameter values of the switching device; and

one or more attachment elements to attach a communication module to the switching device at a defined position such that one or more of the one or more setting elements is covered by the communication module.

At least one embodiment of the invention is directed to a combination, comprising:

the communication module of an embodiment; and

a switching device including one or more setting elements to set parameter values of the switching device; and one or more attachment elements to attach the communication module to the switching device at a defined position such that one or more of the one or more setting elements is covered by the communication module.

At least one embodiment of the invention is directed to a method for converting the parameterization of a switching device including one or more setting elements for setting parameter values of the switching device to remote parameterization, the method comprising:

setting up a communication connection between a communication module for remote parameterization and the switching device, the communication module being attached to the switching device at a defined position relative to the switching device such that the communication module covers one or more of the one or more setting elements; and transmitting parameter values assigned to the one or more covered setting elements, from the communication module via the communication connection, to the switching device.

At least one embodiment of the invention is directed to a non-transitory computer program product for converting the parameterization of a parameterizable switching device, storing a computer program product, executable in a processor of the switching device, to carry out the method of an embodiment when executed.

### BRIEF DESCRIPTION OF THE DRAWINGS

The characteristics, features and advantages of this invention described above and the manner in which they are achieved will become clearer and more readily understandable from the following description of the drawings. Here, in a schematic representation not shown to scale:

FIG. 1 shows the operating side of a switching device according to one example embodiment of the present invention;

FIG. 2 shows the operating side of the switching device shown in FIG. 1 with an attached communication module according to one example embodiment of the present invention;

FIG. 3 shows the cross section from FIG. 2;

FIG. 4 shows an operating side of the switching device shown in FIG. 1 with an attached communication module according to a further example embodiment of the present invention; and

FIG. 5 shows a flow diagram of a computer program product according to one example embodiment of the present invention.

### DETAILED DESCRIPTION OF EXAMPLE EMBODIMENTS

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Various example embodiments will now be described more fully with reference to the accompanying drawings in which only some example embodiments are shown. Specific structural and functional details disclosed herein are merely representative for purposes of describing example embodiments. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Accordingly, known processes, elements, and techniques, may not be described with respect to some example embodiments. Unless otherwise noted, like reference characters denote like elements throughout the attached drawings and written description, and thus descriptions will not be repeated. The present invention, however, may be embodied in many alternate forms and should not be construed as limited to only the example embodiments set forth herein.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “connected,” “engaged,” “interfaced,” and “coupled.” Unless explicitly described as being “direct,” when a relationship between first and second elements is described in the above disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

When an element is referred to as being “on,” “connected to,” “coupled to,” or “adjacent to,” another element, the element may be directly on, connected to, coupled to, or adjacent to, the other element, or one or more other intervening elements may be present. In contrast, when an element is referred to as being “directly on,” “directly connected to,” “directly coupled to,” or “immediately adjacent to,” another element there are no intervening elements present.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Before discussing example embodiments in more detail, it is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments of the present invention. This invention may, however, be embodied in many alternate forms and should not be construed as limited to only the embodiments set forth herein.

Units and/or devices according to one or more example embodiments may be implemented using hardware, software, and/or a combination thereof. For example, hardware devices may be implemented using processing circuitry such as, but not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one embodiment of the invention relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

At least one embodiment of the invention is directed to a communication module. The communication module is a module required for a functional expansion of the switching device in relation to communication. The communication module is suitable for releasable attachment to a parameterizable switching device so that it assumes a defined position relative to the switching device. To do this, the communication module has one or more attachment elements for the attachment of the communication module at a precisely defined position on the switching device, the attachment elements thus acting as positioning device(s). The expression “at a precisely defined position” means that the communication module can be attached via the attachment elements at a defined position on the switching device. A parameterizable switching device is a switching device, e.g. a contactor, a relay or a motor starter, for which parameters can be predefined for its operation. For this purpose, the switching device has one or more setting elements arranged on an operating side of the switching device for setting a parameter value in each case for the individual parameters. A rotary control, for example, which bears a marking that can be set by a user to any value on a scale indicator can serve as a setting element. The setting element is connected via an operative connection to a potentiometer or a rotary coding switch which, as a component of an electrical circuit, defines a corresponding parameter value which is intended to be used during the operation of the switching device. The position defined for the communication model relative to the switching device is such that housing parts of the communication module cover one or more of the setting elements of the switching device when the communication module is attached to the switching device. The covered setting elements can therefore no longer be set and can no longer be read by a user.

According to at least one embodiment of the invention, the communication module has one or more attachment elements with which the communication module can be attached at a predefined position relative to the switching device, i.e. at a precisely defined position. The communication module can have one or more retaining lugs which interact with matching retaining recesses in the switching device. The communication module can also have one or more retaining recesses which interact with matching retaining lugs in the switching device. All other releasable attachment devices such as screws, pins, suspension devices, magnetic connections, etc., with which the communication module can be attached to the switching device are also possible.

At least one embodiment of the invention is further directed to a switching device. The switching device is parameterizable and for this purpose has one or more setting elements for setting parameter values of the switching device. The switching device is further designed in such a way that it interacts with a communication module, i.e. it provides a defined position for the attachment of the communication module. For this purpose, the switching device has one or more attachment elements for the attachment of a communication module at a precisely defined position on the switching device such that one or more of the setting elements of the switching device is covered by the communication module.

According to at least one embodiment of the invention, the switching device has one or more attachment elements which serve to attach the communication module at a predefined position relative to the switching device, i.e. at a precisely defined position, and which therefore act as positioning device(s). The attachment elements of the switching device match the attachment elements arranged on the communication module. The communication module can, for example, have one or more retaining lugs which interact with matching retaining recesses in the switching device. Alternatively, the communication module can also have one or more retaining recesses which interact with matching retaining lugs in the switching device.

At least one embodiment of the invention is further directed to a method. This involves a method for converting the parameterization of a parameterizable switching device from a parameterization directly on the switching device to a remote parameterization, in particular via a communication network and/or a data line. The switching device has one or more setting elements by which parameter values can be set directly on the switching device. The method comprises a first method step in which a communication connection is set up between a communication module for remote parameterization and the switching device, wherein the communication module is attached to the switching device in such a way that the communication module covers one or more of the setting elements of the switching device. Through the setting up of the communication connection, the switching device is notified that the parameter values set on the setting elements are now no longer to be used for those parameters whose setting elements are covered by the communication module, but instead the parameter values which are received from the communication module. It is possible for the definition of the setting elements which are covered by the communication module to be transmitted from the communication module to the switching device. Two or more different communication modules which in each case cover different setting elements of the switching device and therefore also contain different definitions of the setting elements which are covered by the communication module can thus be assigned to one switching device. For permanent storage of the definition, a dataset associated with the communication module and containing this definition can be stored in a non-volatile electronic memory component of the communication module, e.g. an EEPROM (=Electrically Erasable Programmable Read Only Memory). The method also comprises a further step in which parameter values which are assigned to the covered setting elements are transmitted from the communication module via the communication connection to the switching device.

At least one embodiment of the invention is based on the realization that an operation of a setting element of the switching device can best be excluded via a physical covering of the setting element. The attachment of the communication module at a precisely defined position on the switching device results in a covering of defined setting elements by housing parts of the communication module. Since this covering is implemented according to the invention by a communication module which is provided for a remote parameterization of the switching device, it is clearly indicated to the user that the parameter assigned to the covered setting element is not settable directly on the device, but only remotely, e.g. via a communication network or an additional input unit. An ambiguous state in which it is unclear to the user how the parameter is set or which parameter is used in the operation of the switching device is thus avoided for the user.

By way of at least one embodiment of the invention, it is possible to implement switching devices which are parameterizable as stand-alone devices without a communication connection via setting elements, on the basis of potentiometers and rotary coding switches, wherein the selected parameterization is readable from scale indicators of the setting elements, and, with the expansion with an additionally attachable communication module, a comprehensive parameterization is possible without parameter settings on visible setting elements causing uncertainty with regard to the internally used parameters.

Advantageous designs and developments of the invention are indicated in the claims.

According to one preferred development of an embodiment of the invention, the communication module has a transmitter. In a communication connection between the communication module and the switching device, the transmitter serves to transmit parameter values via the communication connection to a receiver of the switching device. In particular, parameter values for those parameters which are assigned to the covered setting elements are transmitted via the communication connection. The communication connection establishes an optical, electrical or electromagnetic connection between the switching device designed as a base unit and the communication module designed as an expansion unit, the connection enabling the transmission of data from the expansion unit to the base unit. In particular, the communication connection can be designed as an optical connection with or without an optical waveguide, or as a wireless connection which enables an electrical isolation between the base unit and the expansion module. The following transmission technologies, for example, can be used for a wireless communication connection which does not require an electrical line-based connection: infrared, Bluetooth, NFC(=Near Field Communication). It is readily possible with a wireless communication connection to implement a safe galvanic isolation between the circuit(s) of the base unit and the circuit of the expansion.

According to one preferred development of an embodiment of the invention, both the communication module and the switching device in each case have a transmitter and a receiver. This enables a bidirectional data exchange between the switching device serving as a base unit and the communication module serving as an expansion module. Datasets can thus be exchanged in both directions; diagnostic data and measurement data, for example, can thus be read from the switching device and transported via the communication module and a communication connection to an analyzing station. The transmitter and the receiver can be designed as a transceiver, e.g. as transmit and receive diodes.

According to one preferred development of an embodiment of the invention, the communication module is designed and the position of the communication module on the switching device is chosen in such a way that the communication module attached at a predefined position relative to the switching device leaves setting elements accessible for ATEX-relevant parameters, i.e. for parameters which are relevant to explosion protection (ATEX =ATEX Directives of the European Union; the designation ATEX is derived from the French abbreviation for ATmosphères EXplosibles). The communication module is therefore fitted to the switching device in such a way that not all of the setting elements present on the switching device are covered and are therefore made accessible: those setting elements which relate to ATEX-relevant parameters, e.g. the rated operating current or nominal current Ie and the motor overload trip class. These ATEX-relevant parameters remain parameterizable exclusively with the setting elements present on the switching device, whereas other parameters whose setting elements are covered are parameterizable only via the communication module. In the case of ATEX-relevant parameters, in the event of a conversion of the parameterization of a parameterizable switching device from a parameterization directly on the switching device to a remote parameterization, i.e. a parameterization via a communication module, substantial outlay is required to ensure that these parameters are received error-free in the switching device. In this respect, it is advantageous in the case of ATEX-relevant parameters to be able to modify them only via setting elements located on the switching device.

According to one preferred development of an embodiment of the invention, the communication module has at least one socket as part of a communication interface for the connection to a communication network. It is also possible for the communication module to have two sockets as parts of communication interfaces: the first socket can be used for the communication connection to a communication network and the second socket for the communication connection to a further communication module; it is also possible for the first socket to be used for the communication connection to a first further communication module and the second socket for the communication connection to a second further communication module. In this way, two or more communication modules can be connected in series. It is possible for only a first communication module of the two or more series-connected communication modules to be connected to a communication network and for the entire data traffic between the communication network and the two or more series-connected communication modules to take place via the first communication module; in this way, the first communication module acts as a common communication interface to the communication network for all communication modules of the two or more series-connected communication modules.

According to one preferred development of an embodiment of the invention, the switching device has a receiver for a communication connection between the communication module and the switching device, wherein the receiver can receive parameter values assigned to the covered setting elements from the communication module via the communication connection. The receiver of the switching device communicates with the transmitter of the communication module.

One preferred design of an embodiment of the invention is formed by a combination of a switching device as described above and a communication module attached to the switching device as described above. The attachment elements of the switching device and the attachment elements of the communication module match one another so that the communication module can be attached only at a defined position on the switching device; the housing parts of the communication module cover only predefined setting elements of the switching device at this position.

One preferred design of an embodiment of the invention is further formed by a combination of a switching device and a communication module attached to the switching device. The switching device has one or more setting elements for setting parameter values of the switching device and one or more attachment elements for attaching the communication module at a precisely defined position, i.e. at a defined position in relation to the switching device. The switching device further has a receiver for a communication connection between the communication module and the switching device. The communication module further has one or more attachment elements for attaching the communication module at a precisely defined position on the switching device, i.e. that a defined position in relation to the switching device. The communication module further has housing parts which cover one or more setting elements of the switching device which serve to set parameter values, so that the covered setting elements can no longer be set and can no longer be read by a user when the communication module is attached to the switching device at the defined position in relation to the switching device. In addition, the communication module has a transmitter for a communication connection between the communication module and the switching device. The transmitter of the communication module can transmit parameter values assigned to the covered setting elements via the communication connection to the switching device, and the receiver of the switching device can receive parameter values assigned to the covered setting elements from the communication module via the communication connection. Through the setting up of the communication connection, the switching device is notified that, for those parameters whose setting elements are covered by the communication module, the parameter values set on the setting elements are now no longer to be used, but instead the parameter values which are received from the communication module.

One preferred design of the method according to an embodiment of the invention is further formed by a method for converting the parameterization of a switching device which has one or more setting elements for setting parameter values of the switching device to remote parameterization, having the following steps:
setting up a communication connection between a communication module for remote parameterization and the switching device, wherein the communication module is attached to the switching device at a defined position relative to the switching device such that the communication module covers one or more of the setting elements; and
transmitting parameter values which are assigned to the covered setting elements from the communication module via the communication connection to the switching device,
wherein the communication module covers the setting elements of the switching device in such a way that the covered setting elements can no longer be set and can no longer be read by a user when the communication module is attached to the switching device at the defined position relative to the switching device, and
wherein, through the setting up of the communication connection, the switching device is notified that the parameter values set on the setting elements are now no longer to be used for those parameters whose setting elements are covered by the communication module, but instead the parameter values which are received from the communication module.

At least one embodiment of the invention is also achieved by a computer program product. This involves a computer program product for converting the parameterization of a parameterizable switching device. The computer program product is designed to be executable in a processor of the switching device. The computer program product can be designed to be storable as software, e.g. as a downloadable application software program (app for short), or as firmware in a memory of the communication module, and to be executable by the processor or a computing unit of the switching device. Alternatively or additionally, one or more functions of the computer program product can be designed as hardware, for example as an ASIC or in the form of a programmable logic circuit, e.g. an FPGA (ASIC =Application-Specific Integrated Circuit; FPGA=Field Programmable Gate Array).

The computer program product according to an embodiment of the invention is designed to carry out the method of an embodiment. The computer program product is therefore designed to carry out the method for converting the parameterization of a parameterizable switching device. In particular, it is designed to carry out the step of setting up a communication connection between a communication module for remote parameterization and the switching device. It is further designed to carry out the step of transmitting parameter values which are assigned to covered setting elements from the communication module via the communication connection to the switching device. The computer program product is designed according to the invention to implement and execute at least one embodiment of the described method for converting the parameterization. The computer program product can bring together all sub-functions of the method, i.e. it can be designed as monolithic.

Alternatively, the computer program product can also be designed as segmented and can in each case distribute sub-functions among segments which are executed on separate hardware. The computer program product can thus be designed to be executable partially in a processor of the switching device and partially in a processor of the communication module. One part of the method can further be carried out in the switching device and/or the communication module and another part of the method can be carried out in the control unit superordinate to the switching device and/or the communication model, such as, for example, a PLC, a manual parameterization device or a computer cloud (PLC=Programmable Logic Controller).

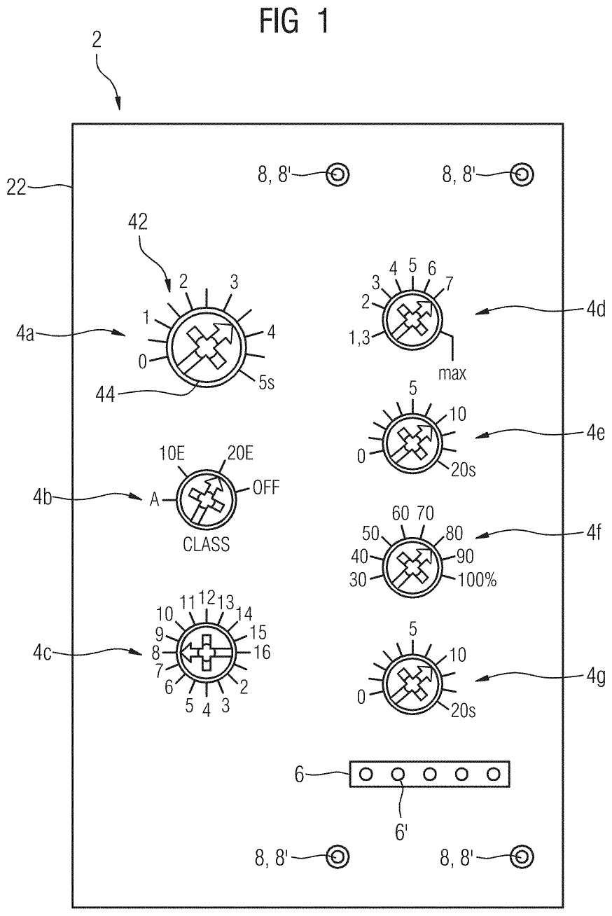

FIG. 1 shows the operating side of a housing 22 of a switching device 2. It has seven setting elements 4a to 4g provided for the setting of parameters and in each case having a rotary control 44 with an arrow-marking and a scale indicator 42 arranged around the rotary control 44. The setting elements 4a to 4g are arranged in two columns. In the left-hand column, one setting element 4a is for the breakaway time, one setting element 4b for the CLASS setting for the motor overload trip class, and one setting element 4c for the rated operating current. In the right-hand column, one setting element 4d is for the current limitation, one setting element 4e for the start-up voltage, one setting element 4f for the start-up ramp time and one setting element 4g for the deceleration time.

In addition, four operating elements 8′ designed as blind holes are provided on the operating side as an attachment device 8 for a communication module, and also a row of holes having passage openings 6′ in the housing 22 and being provided as a communication interface 6 for a communication module.

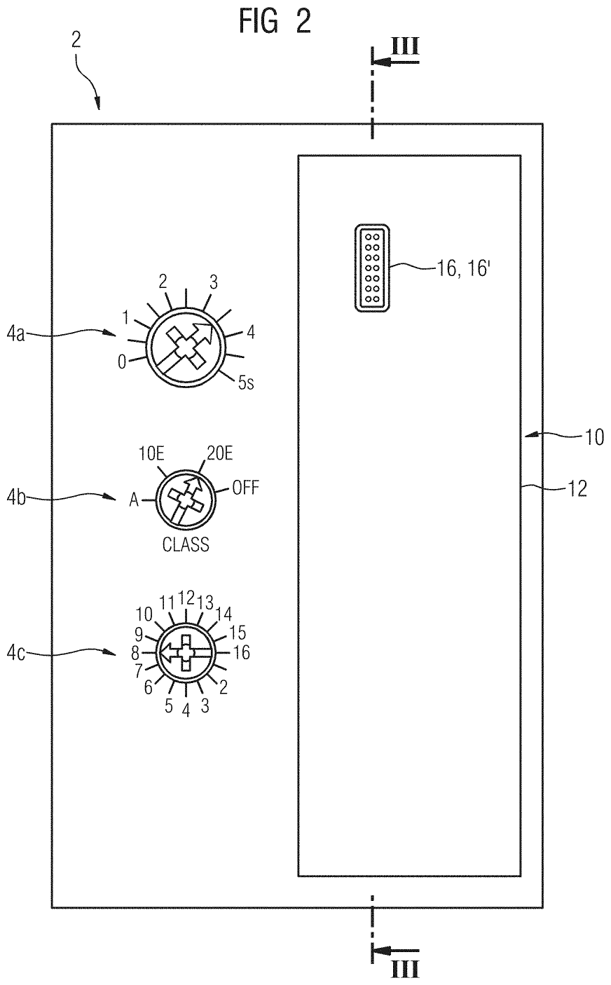

FIG. 2 shows the operating side of the switching device 2 shown in FIG. 1 with an attached communication module 10. For the attachment, the communication module 10 has been inserted into the blind holes 8′ of the housing 22 of the switching device 2 shown in FIG. 1 with attachment elements in the form of pins arranged on a housing 12 of the communication module 10. The housing 12 of the communication module 10 covers all four setting elements 4d to 4g of the right-hand column, but leaves the three setting elements 4a to 4c of the left-hand column accessible for operation. The communication module 10 has a socket 16′ on its side facing the operator as part of a communication interface 16 for connection to a communication network.

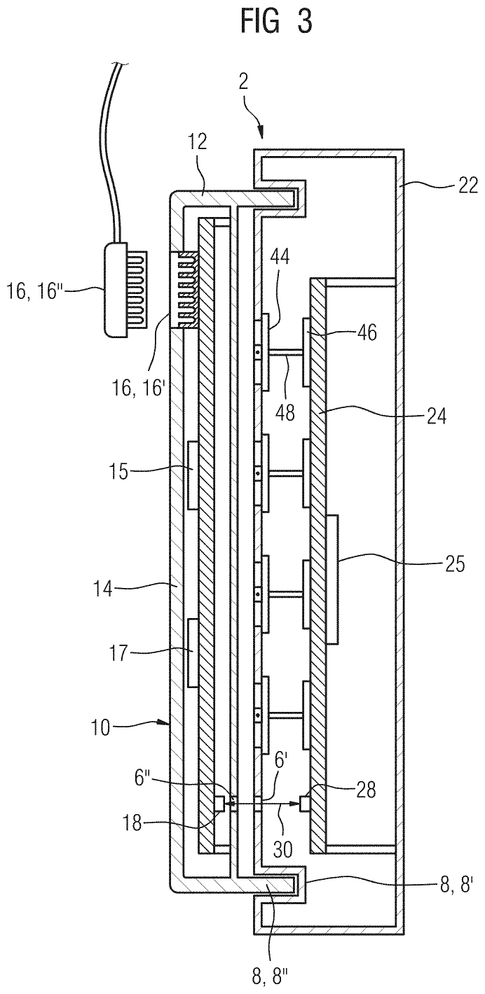

FIG. 3 shows the cross section along the cross section plane III-III shown in FIG. 2. The communication module 10 is attached to the switching device 2. For this purpose, the housing 12 of the communication module 10 has vertically projecting pins 8″ on its underside, i.e. on its side facing the switching device 2, as attachment elements which have been inserted into the blind holes 8′ of the housing 22 of the switching device 2 serving as attachment elements. In this way, the pins 8″ and the blind holes 8′ serve as an attachment device 8 for the attachment of the communication module 10 to the switching device 2 at a precisely defined position.

The switching device 2 has a printed circuit board (PCB) 24 inside its housing 22 which carries potentiometers and rotary coding switches 46 which can be adjusted by the setting elements 4a to 4g via an operative connection 48 in order to set parameters for the operation of the switching device 2.

Inside its housing 12, the communication module 10 has a printed circuit board 14 which carries a socket 16′ as part of the communication interface 16 for connection to a communication network via a network connector 16″ insertable into the socket 16′, and an LED 18 serving as a transmitter. Through matching openings 6′, 6″ in the housings 12, 22 of the communication module 10 and of the switching device 2, the transmitter LED 18 of the communication module 10 is in optical contact with a photodiode 28 which serves as a receiver and is arranged on the printed circuit board 24 of the switching device 2. In this way, a communication connection exists between the communication module 10 and the switching device 2 via which parameter values for those parameters which are assigned to the covered setting elements are transmittable from the communication module 10 to the switching device.

It is also possible for both the communication module 10 and the switching device 2 in each case to have a transmitter and a receiver. This enables a bidirectional data exchange between the switching device 2 serving as a base unit and the communication module 10 serving as an expansion module, i.e. a communication connection configured as bidirectional.

In an alternative design, a multipole electrical contact can also be established through the matching openings 6′, 6″, e.g. via electrically conducting spring elements, between the printed circuit board 14 of the communication module 10 and the printed circuit board 24 of the switching device 2.

The communication module 10 further has a memory 15 and a processor 17 on its printed circuit board 14. A computer program product for converting the parameterization of a parameterizable switching device is stored in the memory 15 which is designed as a non-volatile electronic memory component, e.g. as an EEPROM, wherein the computer program product is executable in a processor 25 of the switching device 2 and is designed to carry out the method according to the invention. The readout of the computer program product from the memory 15 and the transmission of the computer program product via the communication connection 30 to the switching device 2 is controlled by the processor 17 of the communication module 10. The received computer program product is executed in the switching device 2 in a processor 25 arranged on the printed circuit board 24 of the switching device 2.

Via the attachment of the communication module 10 onto the switching device 2, e.g. through the insertion of a pin 8″ into a blind hole 8′, an electrical contact can be established which triggers the processors 15, 25 of the base unit 2 and the expansion module 10 to set up the communication connection 30 via the transmitter 18 and the receiver 28. Through the setting up of the communication connection 30, the switching device 2 is notified that the parameter values set on the setting elements 4d-4g are now no longer to be used for those parameters whose setting elements 4d-4g are covered by the communication module 10, but instead the parameter values which the switching device 2 receives from the communication module 10. Apart from the computer program product for converting the parameterization, the information indicating which of the setting elements 4a-4g of the switching device 2 are covered by the communication module 10 is also contained in the memory 15 of the communication module 10. The definition of the setting elements 4d-4g which are covered by the communication module 10 is transmitted from the communication module 10 to the switching device 2, where it is used for the control performed by the processor 25 of the switching device 2 which determines whether a parameter value set on a setting element 4a-4g of the switching device 2 or a parameter value obtained from the communication module 10 is to be used for a specific parameter in the operation of the switching device.

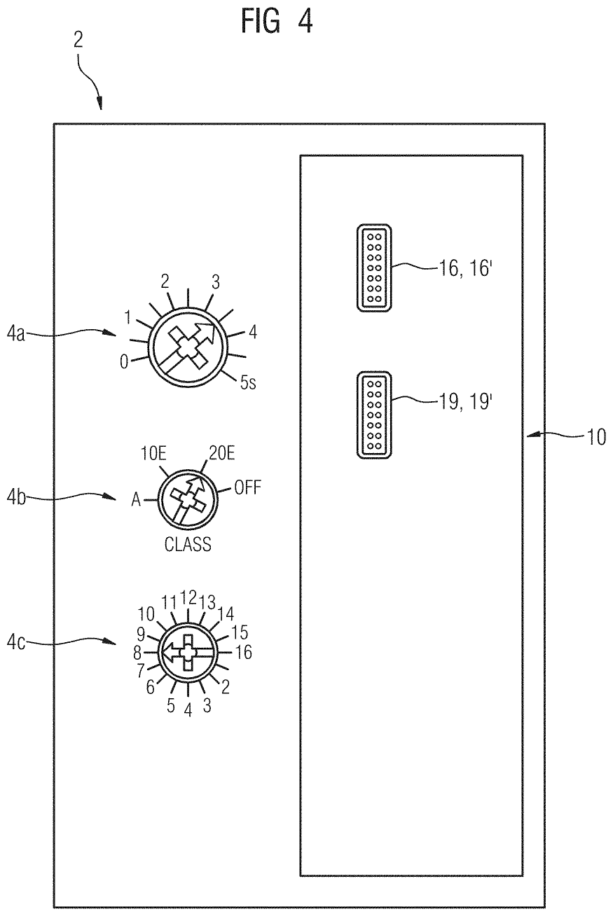

FIG. 4 shows the operating side of the switching device 2 shown in FIG. 1 with an alternative attached communication module 10 which has the following difference compared with the communication module 10 shown in FIG. 2: in addition to the socket 16′ which, as part of a first communication interface 16 for connecting to a communication network, carries the communication module 10 shown in FIG. 2 on its operating side, the communication module shown in FIG. 4 has a further socket 19′ as part of the second communication interface 19 for connecting to a further communication module (not shown) which for its part is similarly attached to a switching device. In this way, two or more communication modules can be connected in series. It is possible for only a first communication module of the two or more series-connected communication modules to be connected to a communication network and for the entire data traffic between the communication network and the two or more series-connected communication modules to flow via the first communication module; in this way, the first communication module acts as a common communication interface to the communication network for all communication modules of the two or more series-connected communication modules.

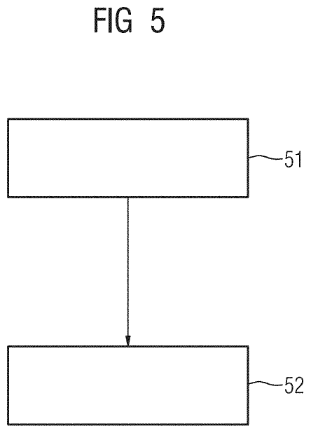

FIG. 5 shows a flow diagram of the claimed method for converting the parameterization of a parameterizable switching device from a parameterization directly on the switching device to a remote parameterization, in particular via a communication network and/or a data line. The method comprises a first method step 51 in which a communication module which is suitable for remote parameterization is attached to the switching device which has one or more setting elements by which the parameter values can be set directly on the switching device, in such a way that the communication module covers one or more of the setting elements. The method comprises a further method step 52 in which a communication connection is set up between the communication module and the switching device. The method also comprises a further method step 53 in which parameter values which are assigned to the covered setting elements are transmitted from the communication module via the communication connection to the switching device.

In addition, it should be made clear that functions of any one of the above-described embodiments may be implemented not only by executing program code read by a computer but also by causing, according to an instruction given by program code, an operating system, etc. running on a computer to complete part or all of actual operations.

In addition, it can be understood that functions of any one of the above-described embodiments may be implemented by writing program code read from a storage medium to a memory disposed in an expansion board inserted into a computer or to a memory disposed in an expansion unit connected to a computer, and then by, according to the instruction of program code, causing a CPU, etc. installed on the expansion board or expansion unit to execute part or all of actual operations.

It should be noted that not all the steps or modules in the above-described flows and system structural diagrams are required, and certain steps or modules may be omitted as needed. The sequence of executing steps is not fixed and may be adjusted as needed. The system structures described in the above embodiments may be physical structures or logical structures; in other words, certain modules may be implemented as the same physical entity, or certain modules may be implemented as at least two physical entities separately, or certain modules may be jointly implemented by certain components in at least two standalone devices.

In each of the above embodiments, a hardware unit may be implemented mechanically or electrically. For example, a hardware unit may comprise a permanently dedicated circuit or logic, for example, a special processor, an FPGA, or an ASIC, for completing corresponding operations. A hardware unit may further comprise programmable logic or circuitry (for example, a general-purpose processor or any other programmable processor), which may be temporarily configured by software to perform corresponding operations. Specific implementations (mechanical, or dedicated permanent circuits, or temporarily configured circuits) may be determined on the basis of cost and time considerations.

While the present invention has been described and illustrated in detail above with reference to the drawings and preferred embodiments, the present invention is not limited to these disclosed embodiments, and more embodiments of the present invention may be obtained by combining the code auditing means in the different embodiments described above, as may be appreciated by those of ordinary skill in the art based on the abovementioned embodiments; these embodiments also fall within the protection scope of the present invention.

The patent claims of the application are formulation proposals without prejudice for obtaining more extensive patent protection. The applicant reserves the right to claim even further combinations of features previously disclosed only in the description and/or drawings.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

None of the elements recited in the claims are intended to be a means-plus-function element within the meaning of 35 U.S.C. § 112(f) unless an element is expressly recited using the phrase “means for” or, in the case of a method claim, using the phrases “operation for” or “step for.”

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A communication module for attachment to a parameterizable switching device, comprising:
one or more attachment elements for the attachment of the communication module to the switching device at a defined position; and
housing parts to, upon the communication module being attached to the switching device, cover one or more setting elements, of the switching device, usable to set parameter values.

2. The communication module of claim 1, further comprising:
a transmitter for a communication connection between the communication module and the switching device, wherein the transmitter is configured to transmit parameter values assigned to the setting elements, when covered, via the communication connection to the switching device.

3. The communication module of claim 1, further comprising:
a transmitter and a receiver for a bidirectional communication connection between the communication module and the switching device.

4. The communication module of claim 1, wherein the communication module, attached at the defined position relative to the switching device, permits accessibility to the one or more setting elements, accessible for ATEX-relevant parameters.

5. A switching device, comprising:
one or more setting elements to set parameter values of the switching device; and
one or more attachment elements to attach a communication module to the switching device at a defined position such that one or more of the one or more setting elements is covered by the communication module.

6. The switching device of claim 5, further comprising:
a receiver for a communication connection between the communication module and the switching device, wherein the receiver is configured to receive parameter values assigned to the one or more covered setting elements from the communication module, via the communication connection.

7. The switching device of claim 5, further comprising:
a transmitter and a receiver for a bidirectional communication connection between the communication module and the switching device.

8. A combination, comprising:
the communication module of claim 1; and
a switching device including
one or more setting elements to set parameter values of the switching device; and
one or more attachment elements to attach the communication module to the switching device at a defined position such that one or more of the one or more setting elements is covered by the communication module.

9. A combination comprising:
the communication module of claim 2; and
a switching device including
one or more setting elements to set parameter values of the switching device;
one or more attachment elements to attach the communication module to the switching device at a defined position such that one or more of the one or more setting elements is covered by the communication module, and
a receiver for a communication connection between the communication module and the switching device, wherein the receiver is configured to receive parameter values assigned to the one or more covered setting elements from the communication module, via the communication connection, the communication module being attached to the switching device,
wherein covered housing parts cover the one or more setting elements of the switching device such that the one or more covered setting elements are no longer settable and no longer readable by a user upon the communication module being attached to the switching device, and
wherein, through setting up of the communication connection, the switching device is notified that parameter values set on the one or more setting elements are no longer usable for parameters whose corresponding one or more setting elements are covered by the communication module, but are usable for parameter values received from the communication module.

10. A method for converting the parameterization of a switching device including one or more setting elements for setting parameter values of the switching device to remote parameterization, the method comprising:
setting up a communication connection between a communication module for remote parameterization and the switching device, the communication module being attached to the switching device at a defined position relative to the switching device such that the communication module covers one or more of the one or more setting elements; and
transmitting parameter values assigned to the one or more covered setting elements, from the communication module via the communication connection, to the switching device.

11. The method of claim 10, wherein the communication module covers the one or more setting elements of the switching device such that the one or more covered setting elements are no longer settable and no longer readable by a user upon the communication module being attached to the switching device, the method further comprising:
notifying, through the setting up of the communication connection, the switching device that the parameter values set on the one or more setting elements are no longer usable for parameters whose corresponding one or more setting elements are covered by the communication module, but are usable for parameter values received from the communication module.

12. A non-transitory computer program product for converting the parameterization of a parameterizable switching device, storing a computer program product, executable in a processor of the switching device, to carry out the method of claim 10 when executed.

13. The communication module of claim 2, further comprising:
a transmitter and a receiver for a bidirectional communication connection between the communication module and the switching device.

14. The communication module of claim 2, wherein the communication module, attached at the defined position relative to the switching device, permits accessibility to the one or more setting elements, accessible for ATEX-relevant parameters.

15. The communication module of claim 3, wherein the communication module, attached at the defined position relative to the switching device, permits accessibility to the one or more setting elements, accessible for ATEX-relevant parameters.

16. The switching device of claim 6, further comprising:
a transmitter for a bidirectional communication connection, in connection with the receiver, between the communication module and the switching device.

17. A combination, comprising:
the communication module of claim 2; and
a switching device including
one or more setting elements to set parameter values of the switching device; and
one or more attachment elements to attach the communication module to the switching device at a defined position such that one or more of the one or more setting elements is covered by the communication module.

18. A non-transitory computer program product for converting the parameterization of a parameterizable switching device, storing a computer program product, executable in a processor of the switching device, to carry out the method of claim 11 when executed.
